(19) United States
(12) Patent Application Publication
(10) Pub. No.: US 2009/0232197 A1
(43) Pub. Date: Sep. 17, 2009

(54) PULSE MODULATED WIRELESS COMMUNICATION DEVICE

(75) Inventors: Masahiro Mimura, Tokyo (JP); Suguru Fujita, Tokyo (JP); Kazuaki Takahashi, Tokyo (JP)

Correspondence Address: RATNERPRESTIA, P.O. BOX 980, VALLEY FORGE, PA, 19482, US

(73) Assignee: MATSUSHITA ELECTRIC INDUSTRIAL CO., LTD., Osaka (JP)

(21) Appl. No.: 11/720,683

(22) PCT Filed: Feb. 7, 2006
(86) PCT No.: PCT/JP06/02018

§ 371 Date: Jun. 1, 2007

(30) Foreign Application Priority Data
Feb. 9, 2005 (JP) JP 2005-032563
Jan. 27, 2006 (JP) JP 2006-018832

(51) Int. Cl. H03K 7/04

(52) U.S. Cl. 375/239

(57) ABSTRACT

The transmission device includes a first transmission RF part for RF modulating the pulse signal generated at the timing of a clock signal so as to generate a clock RF signal and for outputting the clock RF signal to a synchronization signal channel; a transmission data generator for generating transmission data in synchronization with the timing of the clock signal; a PPM modulator for PPM modulating the transmission data and for outputting a PPM modulation signal; and a second transmission RF part for RF modulating the PPM modulation signal so as to generate a data RF signal and for outputting the data RF signal to a data signal channel different from the synchronization signal channel. The reception device receives reference synchronization information so as to maintain phase synchronization in data reception.

THIS APPLICATION IS A U.S. NATIONAL PHASE APPLICATION OF PCT INTERNATIONAL APPLICATION PCT/JP2006/302018.

### TECHNICAL FIELD

The present invention relates to a pulse-modulated wireless communication device using pulsed modulated signals.

### BACKGROUND ART

With the recent spread of wireless LAN (Local Area Network), mobile terminal devices are being increasingly used because of their mobility, which is one of the benefits of wirelessness. Mobile terminal devices are highly valued to have (1) a small and lightweight body and (2) a longer battery life (reduced power consumption) and are also required to provide (3) high communication speed.

As a wireless communication technology suitable for LAN applications, UWB (Ultra Wide Band) technology has been drawing attention these days because of the following advantages: (1) suitability for CMOS to achieve size reduction because linearity is not always necessary; (2) low power consumption due to no need for an RF circuit such as a high-precision local signal source; and (3) high speed communication using a wide band width.

Conventionally, pulse-modulated wireless communication devices using pulsed modulated signals demodulate a received signal as follows. The low frequency component of the received signal is extracted; the frequency of a clock tuning signal is adjusted; and a pulse is detected based on the frequency (see, for example, Japanese Translation of PCT Publication No. H10-508725).

The conventional art will be described as follows with a drawing.

FIG. 13 is a block diagram showing a structure of a reception device of a conventional pulse-modulated wireless communication device based on UWB using pulsed modulated signals.

With FIG. 13, a conventional example using PPM (Pulse Position Modulation) as a modulation scheme will be described as follows.

In FIG. 13, reception device 1300 of the conventional pulse-modulated wireless communication device includes antenna 1301, receiving RF part 1302, correlator 1304, pulse generator 1305, low-pass filter 1307, adjustable time base 1309, pulse timing generator 1311, spreading code sequence generator 1312, and demodulator 1316.

In this structure, antenna 1301 receives a signal, and receiving RF part 1302 amplifies it or eliminates undesired signals so as to generate reception signal 1303.

Correlator 1304 detects correlation between reception signal 1303 and pulse 1315, which is generated by pulse generator 1305, and then generates correlation signal 1306.

Low-pass filter 1307 extracts low frequency component signal 1308 from correlation signal 1306.

Adjustable time base 1309, which is a frequency-variable clock oscillating means, monitors low frequency component signal 1308 and adjusts the frequency of clock tuning signal 1310 to be generated in such a manner as to maximizes signal 1308.

In the technology disclosed in the aforementioned Japanese Translation of PCT Publication No. H10-508725, a spread spectrum technology is applied to spreading code sequence generator 1312 in order to distinguish devices that are not targets of communication. Pulse timing generator 1311 provides clock tuning signal 1310 with a delay corresponding to spreading code sequence signal 1313 generated by spreading code sequence generator 1312, and then provides pulse generation timing signal 1314 to pulse generator 1305.

Thus, in the conventional pulse-modulated wireless communication device, when spreading code sequence signal 1313 generated by spreading code sequence generator 1312 matches the spreading code sequence signal from the transmission device, correlator 1304 performs pulse detection and reverse spreading, and then demodulator 1316 performs a demodulation process to generate a baseband signal sequence.

The conventional pulse-modulated wireless communication devices, however, are required to have a complicated synchronization circuit that regenerates a synchronization signal from a modulated wave with high precision. The reason for this is as follows. When the conventional devices are based, for example, on pulse position modulation in which the temporal position of a pulse provides some information, the pulse train to be obtained as a reception signal is not periodic, so that it is also necessary to detect pulse displacement.

When the conventional devices are based, on the other hand, on multi-valued pulse position modulation, a much complicated synchronization circuit is required to detect the temporal position of a pulse with high precision.

When the conventional devices achieve frame synchronization by providing a transmission signal with a preamble part containing a periodic pulse train at the time of subjecting a received signal to a demodulation process, the provision of the preamble part, which contains no information, results in a reduction in the substantial data transmission rate.

Another problem of the conventional pulse-modulated wireless communication devices is as follows. The synchronization process is performed intermittently in the preamble part only. Therefore, if the preamble part is affected by undesired interference waves such as electric waves due to multipath propagation or from other devices, it disrupts the synchronization timing, thereby extremely degrading the receiving performance.

### SUMMARY OF THE INVENTION

To solve these problems, an object of the present invention is to provide a pulse-modulated wireless communication device in which the reception device of the device can appropriately receive reference synchronization information used in pulse modulation so as to maintain the state of synchronization, for example, in pulse position, and data signals can be started to be demodulated soon after they are received, so that pulse-modulated data signals can be received by a simple-structured synchronization circuit.

Another object of the present invention is to provide a pulse-modulated wireless communication device in which a data signal modulated, for example, by multi-valued pulse position modulation can be received by a simple-structured synchronization circuit.

Another object of the present invention is to provide a pulse-modulated wireless communication device which has high reliability in detecting errors in data signals.

Another object of the present invention is to provide a pulse-modulated wireless communication device which does not require a high-precision synchronization circuit after a synchronization channel is pulled into synchronism, thereby improving the communication efficiency of a synchronization channel signal.

Another object of the present invention is to provide a pulse-modulated wireless communication device which has a high efficiency of use of a synchronization channel signal when performing data communication concurrently with a plurality of pulse-modulated wireless communication devices.

The pulse-modulated wireless communication device of the present invention includes: a clock generator for generating a clock signal indicating each frame timing of a transmission signal; a first pulse generator for generating a pulse signal at the timing of the clock signal; a first transmission converter for signal-converting the pulse signal generated by the first pulse generator so as to generate a clock conversion signal and for outputting the clock conversion signal to a synchronization signal channel; a transmission data generator for generating transmission data in synchronization with the timing of the clock signal; a pulse modulator for pulse-modulating the transmission data and outputting a pulse generation timing signal; a second pulse generator for generating a pulse signal at the timing of the pulse generation timing signal; and a second transmission converter for signal-converting the pulse signal generated by the second pulse generator so as to generate a data conversion signal and for outputting the data conversion signal to a data signal channel different from the synchronization signal channel.

The pulse-modulated wireless communication device of the present invention may include: a first reception converter for receiving a clock conversion signal from a synchronization signal channel, the clock conversion signal being obtained by signal-converting a clock pulse signal, and for generating the clock pulse signal; a second reception converter for receiving a data conversion signal from a data signal channel different from the synchronization signal channel, the data conversion signal being obtained by signal-converting a data pulse signal, and for generating the data pulse signal; a pulse demodulator for pulse-demodulating the data pulse signal on the basis of the clock pulse signal and for outputting a bit stream; and a demodulator for demodulating the bit stream into reception data on the basis of the clock pulse signal.

In the pulse-modulated wireless communication device of the present invention, the pulse modulator may include: a pulse position setting part for setting modulated pulse positions indicating pulse positions of pulse modulation in accordance with the transmission data and for outputting pulse control signals corresponding to the modulated pulse positions; a plurality of multi-stage delay parts for tap-outputting the clock signals delayed respectively according to all the pulse positions of pulse modulation; and a plurality of switches for selecting and outputting output signals of the plurality of multi-stage delay parts in accordance with the pulse control signals.

In the pulse-modulated wireless communication device of the present invention, the pulse demodulator may include: a plurality of multi-stage delay parts for outputting the clock pulse signals delayed respectively according to all the pulse positions of pulse modulation; a plurality of correlators for detecting correlation between output signals of the plurality of multi-stage delay parts and the data pulse signal and for outputting correlation signals; and a pulse position determining part for determining the pulse positions of pulse modulation in accordance with the correlation signals and for outputting a bit stream.

The pulse-modulated wireless communication device of the present invention may further include: a synchronization generator for generating a synchronizing pulse signal, the synchronizing pulse signal being a pulse signal having a constant cycle in accordance with the clock signal, wherein the first pulse generator generates a pulse signal at the timing of the synchronizing pulse signal.

The pulse-modulated wireless communication device of the present invention may further include: a clock regenerator for generating a regeneration clock signal from a clock pulse signal, the regeneration clock signal indicating each frame timing, and the clock pulse signal having a constant cycle, wherein the pulse demodulator pulse-demodulates the data pulse signal on the basis of the regeneration clock signal and outputs a bit stream; and the demodulator demodulates the bit stream into reception data on the basis of the regeneration clock signal.

In the pulse-modulated wireless communication device of the present invention, the clock regenerator may include: a clock signal source operating at a frequency close to a preset frame timing and capable of being frequency-controlled by an external voltage; a phase comparator for outputting an amount of error indicating a phase difference between the clock signal source and the clock pulse signal; and a low-pass filter for converting the amount of error to a control voltage and for outputting the control voltage, and the clock regenerator controls the frequency of the clock signal source by the control voltage.

In the pulse-modulated wireless communication device of the present invention, the clock regenerator may include: a clock regeneration signal generator operating at a frequency close to a preset frame timing and capable of being reset in such a manner that an output signal of the clock regeneration signal generator restores the initial phase by an external signal, the clock regeneration signal generator synchronizing the phase of the regeneration clock signal with the clock pulse signal, upon receiving the clock pulse signal.

The pulse-modulated wireless communication device of the present invention may further include: a superimposed data generator for generating a superimposed pulse signal, the superimposed pulse signal consisting of a pulse signal having a constant cycle in accordance with the clock signal, and a pulse signal obtained by superimposing additional information data indicating additional information of the transmission data onto the clock signal, wherein the transmission data generator generates the additional information data together with the transmission data in synchronization with the timing of the clock signal, and the first pulse generator generates a pulse signal at a timing of the superimposed pulse signal.

The pulse-modulated wireless communication device of the present invention may further include: a clock regenerator for generating a regeneration clock signal from a clock pulse signal, the regeneration clock signal indicating each frame timing, and the clock pulse signal being obtained by superimposing a pulse signal having a constant cycle with additional information data indicating additional information of the transmission data; and a superimposed data decoder for generating superimposed data by extracting the additional information data from the clock pulse signal in accordance with the regeneration clock signal, wherein the demodulator demodulates the superimposed data and the bit stream into reception data on the basis of the reproduction clock signal.

The pulse-modulated wireless communication device of the present invention may further include: a pseudorandom number generator for generating pseudorandom number sequence data in accordance with the clock signal; and a clock pulse modulator for generating a random number pulse signal by pulse-modulating the clock signal in accordance with the pseudorandom number sequence data, wherein the first pulse generator generates a pulse signal at the timing of the random number pulse signal.

The pulse-modulated wireless communication device of the present invention may further include: a clock pulse demodulator for generating a random number regeneration clock signal from a clock pulse signal, the random number regeneration clock signal indicating each frame timing, and the clock pulse signal being pulse-modulated in accordance with pseudorandom number sequence data; and a pseudorandom number generator for generating the pseudorandom number sequence data at the timing of the random number regeneration clock signal, wherein the pulse demodulator pulse-demodulates the data pulse signal on a basis of the random number regeneration clock signal, and outputs a bit stream, and the demodulator demodulates the bit stream into reception data on the basis of the random number regeneration clock signal.

The pulse-modulated wireless communication device of the present invention may further include: a pseudorandom number generator for generating pseudorandom number sequence data in accordance with the clock signal; and a bi-phase modulator for generating a random number pulse signal by bi-phase modulating (two-valued phase modulating) the clock signal in accordance with the pseudorandom number sequence data, wherein the first pulse generator generates a pulse signal at the timing of the random number pulse signal.

The pulse-modulated wireless communication device of the present invention may further include: a pulse detector for detecting the repetition frequency of bi-phase modulation from a clock pulse signal which is bi-phase modulated in accordance with pseudorandom number sequence data and for generating a bi-phase regeneration clock signal indicating each frame timing, wherein the pulse demodulator pulse-demodulates the data pulse signal on the basis of the bi-phase regeneration clock signal and outputs a bit stream; and the demodulator demodulates the bit stream into reception data on the basis of the bi-phase regeneration clock signal.

The pulse-modulated wireless communication device of the present invention may include: the plurality of transmission data generators; the plurality of pulse modulators; the plurality of second pulse generators; and the plurality of second transmission converters, wherein the transmission data to be transmitted to a plurality of destination devices is modulated to be synchronous with the timing of the clock signal so as to generate the data conversion signal, and is then transmitted to the data signal channels set correspondingly to the destination devices.

In the pulse-modulated wireless communication device of the present invention, the second reception converter may select and receive a preset one of the data conversion signals from the plurality of data signal channels so as to generate the data pulse signal.

In the pulse-modulated wireless communication device of the present invention, the pulse modulator or the pulse demodulator may be based on one of pulse amplitude modulation in which pulse amplitude is modulated; pulse phase modulation in which pulse phase is modulated; and pulse frequency modulation in which pulse frequency is modulated.

In the pulse-modulated wireless communication device of the present invention, the synchronization signal channel may use a frequency band narrower than the data signal channels.

By the aforementioned structure, the present invention can achieve the following pulse-modulated wireless communication device. The reception device of the device can appropriately receive reference synchronization information used in PPM modulation to maintain the state of synchronization in pulse position, and data signals can be started to be demodulated soon after they are received, so that pulse position modulated data signals can be received by a simple-structured synchronization circuit.

The present invention can also achieve a pulse-modulated wireless communication device in which a synchronization pulse train is transmitted at a specified symbol rate and a clock pulse is regenerated on the reception device side, thereby enabling a data signal modulated by multi-valued pulse position modulation to be received using a simple-structured synchronization circuit.

The present invention can also achieve a pulse-modulated wireless communication device in which a synchronization pulse train is transmitted at a specified symbol rate, and additional information such as parity bits is superimposed onto a synchronization signal so as to detect or correct errors in a data signal, thereby improving the reliability of the device.

The present invention can also achieve a pulse-modulated wireless communication device in which a synchronization signal modulated by a random pattern is transmitted to a synchronization channel and regenerated by the same random pattern on the transmission device side so as to smooth the frequency spectrum of a clock RF signal. As a result, after the synchronization channel is pulled into synchronism, no high precision synchronization circuit is necessary, thereby improving the communication efficiency of the synchronization channel signal.

The present invention can also achieve a pulse-modulated wireless communication device in which the use of bi-phase modulation enables the reception device to detect the basic pulse interval of bi-phase modulation by envelope detection or other methods, thereby simplifying the structure of the device.

The present invention can also achieve a pulse-modulated wireless communication device in which when a plurality of pulse-modulated wireless communication devices perform data communication concurrently, a synchronization channel can be shared among a plurality of transmission channels so as to improve the use efficiency of a synchronization channel signal.

The present invention can also achieve a pulse-modulated wireless communication device in which the total frequency band of the synchronization signal channel and the data signal channel can be reduced to improve the communication efficiency per frequency.

### BRIEF DESCRIPTION OF THE DRAWINGS

FIG. 1a is a block diagram showing a structure of a transmission device of a pulse-modulated wireless communication device of a first embodiment of the present invention.

FIG. 1b is a block diagram showing a structure of a reception device of the pulse-modulated wireless communication device of the first embodiment of the present invention.

FIG. 2a is a block diagram showing a structure of a PPM modulator of the pulse-modulated wireless communication device of the first embodiment of the present invention.

FIG. 2b is a view showing a structure of a mapping table stored in a pulse position setting part of the PPM modulator of the first embodiment of the present invention.

FIG. 3a is a block diagram showing a structure of a PPM demodulator of the pulse-modulated wireless communication device of the first embodiment of the present invention.

FIG. 3b is a view showing waveforms of signals in the vicinity of the PPM demodulator of the first embodiment of the present invention.

FIG. 4a is a block diagram showing a structure of a transmission device of a pulse-modulated wireless communication device of a second embodiment of the present invention.

FIG. 4b is a block diagram showing a structure of a reception device of the pulse-modulated wireless communication device of the second embodiment of the present invention.

FIG. 5a is a block diagram showing a structure of a clock regenerator of the pulse-modulated wireless communication device of the second embodiment of the present invention.

FIG. 5b is a block diagram showing another structure of the clock regenerator of the pulse-modulated wireless communication device of the second embodiment of the present invention.

FIG. 6a is a block diagram showing a structure of a transmission device of a pulse-modulated wireless communication device of a third embodiment of the present invention.

FIG. 6b is a block diagram showing a structure of a reception device of the pulse-modulated wireless communication device of the third embodiment of the present invention.

FIG. 7a is a block diagram showing a structure of a transmission device of a pulse-modulated wireless communication device of a fourth embodiment of the present invention.

FIG. 7b is a block diagram showing a structure of a reception device of the pulse-modulated wireless communication device of the fourth embodiment of the present invention.

FIG. 8a is a block diagram showing a structure of a transmission device of a pulse-modulated wireless communication device of a fifth embodiment of the present invention in a case where the modulator uses bi-phase modulation.

FIG. 8b is a block diagram showing a structure of a reception device of the pulse-modulated wireless communication device of the fifth embodiment of the present invention in the case where the modulator uses bi-phase modulation.

FIG. 9a is a block diagram showing a structure of a transmission device of a pulse-modulated wireless communication device of a sixth embodiment of the present invention.

FIG. 9b is a block diagram showing a structure of a reception device of a first pulse-modulated wireless communication device of the sixth embodiment of the present invention.

FIG. 9c is a block diagram showing a structure of a reception device of a second pulse-modulated wireless communication device of the sixth embodiment of the present invention.

FIG. 10a is a block diagram showing a structure of a transmission device of a pulse-modulated wireless communication device of a seventh embodiment of the present invention.

FIG. 10b is a block diagram showing another structure of the transmission device of the pulse-modulated wireless communication device of the seventh embodiment of the present invention.

FIG. 11a is a block diagram showing a structure of a reception device of the pulse-modulated wireless communication device of the seventh embodiment of the present invention.

FIG. 11b is a block diagram showing another structure of the reception device of the pulse-modulated wireless communication device of the seventh embodiment of the present invention.

FIG. 12a is a waveform of a signal received by an antenna of the pulse-modulated wireless communication device of the seventh embodiment of the present invention.

FIG. 12b is an enlarged main view of the waveform of the signal received by the antenna of the pulse-modulated wireless communication device of the seventh embodiment of the present invention.

FIG. 12c is a waveform of a signal outputted from a band-limiting filter of the pulse-modulated wireless communication device of the seventh embodiment of the present invention.

FIG. 12d is an enlarged main view of the waveform of the signal outputted from the band-limiting filter of the pulse-modulated wireless communication device of the seventh embodiment of the present invention.

FIG. 13 is a block diagram showing a structure of a reception device of a conventional pulse-modulated wireless communication device.

### REFERENCE MARKS IN THE DRAWINGS

100a, 200a, 300a, 400a, 500a, 600a transmission device
100b, 200b, 300b, 400b, 500b, 600b, 600c reception device
101 clock generator
102 clock signal
103, 903 transmission data generator
104, 904 PPM modulator
105 pulse generation timing signal
106, 109, 906 pulse generator
107, 110, 907, 1001 transmission RF part
108, 111, 121, 124, 908, 921, 924, 1005, 1105 antenna
112 transmission data
113, 114, 1002, 1104 pulse signal
122, 125, 922, 925, 1101, 1106 reception RF part
123 clock pulse signal
126 data pulse signal
127, 927 PPM demodulator
128 bit stream
129, 929 demodulator
201 pulse position setting part
312 pulse position determining part
401 synchronization generator
402, 402a, 402b clock regenerator
403 synchronizing pulse signal
404 regeneration clock signal
405 synchronization request signal
601 superimposed data generator
602 superimposed data decoder
603 additional information data
604 superimposed pulse signal
605 superimposed data
701, 703 pseudorandom number generator
702 clock PPM modulator
704 clock PPM demodulator
705, 707 pseudorandom number sequence data
801 bi-phase modulator
802 pulse detector
803 random number pulse signal
804 bi-phase regeneration clock signal
A clock RF signal
B, C data RF signal
1003, 1102 RF signal source
1004, 1006a, 1006b pulse shortening circuit
1007 clock signal-based pulse signal
1008 transmission data-based pulse signal
1103 down mixer
1107 band-limiting filter

### DETAILED DESCRIPTION OF PREFERRED EMBODIMENTS

A pulse-modulated wireless communication device of embodiments of the present invention will be described as follows with reference to accompanying drawings.

### First Exemplary Embodiment

The pulse-modulated wireless communication device of a first embodiment of the present invention performs communication operations as follows. When data is sent out, the transmission data is subjected to 4-PPM modulation. A data RF signal (data conversion signal) and a clock RF signal (clock conversion signal) are transmitted respectively through a data signal channel and a synchronization signal channel different from the data signal channel. On the other hand, when data is received, a data RF signal and a clock RF signal are received respectively from the data signal channel and the synchronization signal channel different from the data signal channel. The signals are subjected to 4-PPM demodulation to demodulate and reproduce the data.

In the 4-PPM modulation scheme, a transmission signal has four states, and an impulse is generated by changing the amount of delay in a frame to 0 seconds or “T” seconds. The transmission data of one input clock signal is modulated by two bits at a time. Note that “T” seconds is a shift value in PPM modulation and generally set to a time period shorter than the clock signal interval.

The pulse-modulated wireless communication device of the present embodiment has the following structure.

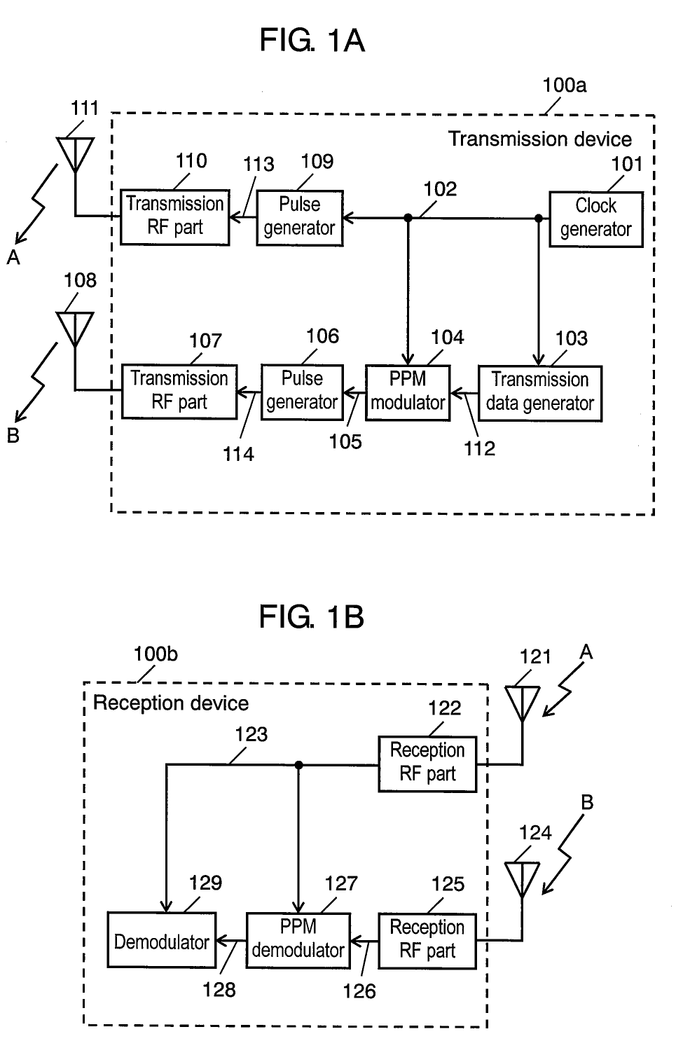

FIG. 1a is a block diagram showing a structure of a transmission device of a pulse-modulated wireless communication device of the present first embodiment.

In FIG. 1a, transmission device 100a is connected to antennas 108 and 111 and includes clock generator 101, transmission data generator 103, and PPM modulator 104. Clock generator 101 generates clock signal 102 at regular intervals of the signal transmission frame rate. Transmission data generator 103 generates transmission data 112 at intervals of clock signal 102. PPM modulator 104 generates pulse generation timing signal 105 by changing the delay of clock signal 102 in accordance with the transmission data.

Transmission device 100a further includes pulse generator 109, transmission RF part 110, pulse generator 106, and transmission RF part 107. Pulse generator 109 generates pulse signal 113 at the generation timing of clock signal 102. Transmission RF part 110 provides pulse signal 113 with an RF (Radio Frequency) process such as amplification and then transmits clock RF signal “A” as a clock conversion signal from antenna 111. Pulse generator 106 generates pulse signal 114 in accordance with the generation timing of pulse generation timing signal 105. Transmission RF part 107 provides pulse signal 114 with an RF process such as amplification and then transmits data RF signal “B” as a data conversion signal from antenna 108.

FIG. 1b is a block diagram showing a structure of a reception device of the pulse-modulated wireless communication device of the present first embodiment.

Reception device 100b is connected to antennas 121 and 124 and includes reception RF part 122 and reception RF part 125. Reception RF part 122 obtains clock pulse signal 123 by removing undesired frequency components from clock RF signal “A” received by antenna 121. Reception RF part 125 obtains data pulse signal 126 by removing undesired frequency components from data RF signal “B” received by antenna 124.

Reception device 100b further includes PPM demodulator 127 and demodulator 129. PPM demodulator 127 detects the position of data pulse signal 126 relative to clock pulse signal 123 within a frame so as to perform PPM demodulation and outputs bit stream 128. Demodulator 129 demodulates the data in bit stream 128.

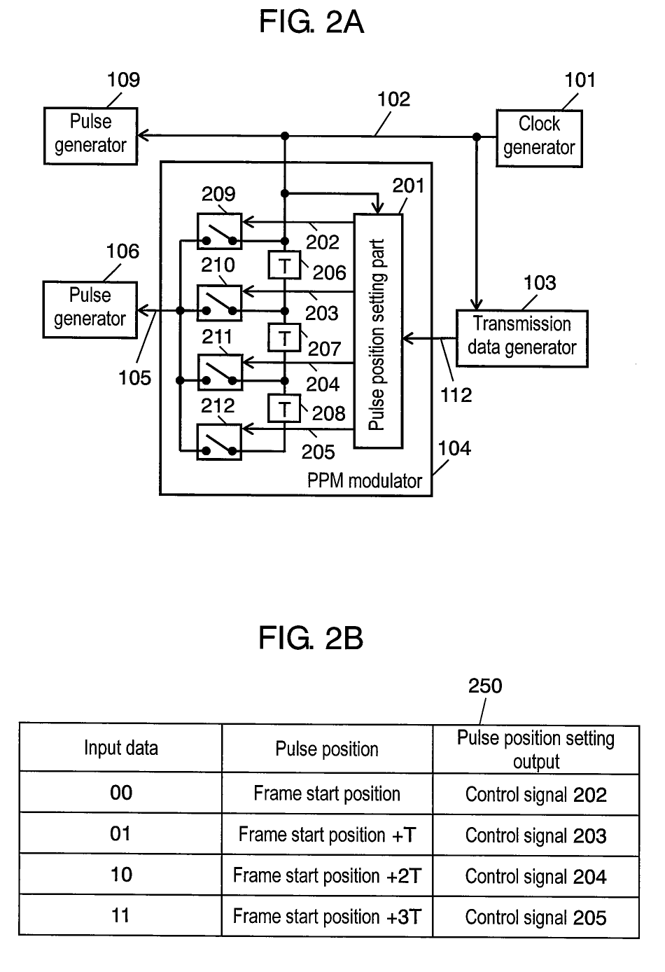

FIG. 2a is a block diagram showing a structure of a PPM modulator of the pulse-modulated wireless communication device of the present first embodiment.

In FIG. 2a, PPM modulator 104 includes pulse position setting part 201, delay elements 206, 207 and 208, and control switches 209, 210, 211 and 212. Pulse position setting part 201 detects the start timing of the frame from clock signal 102 and outputs control signals 202, 203, 204 and 205 indicating the pulse positions in the frame in accordance with inputted transmission data 112. Delay elements 206-208 output the respective input signals with a delay of time “T”. Control switches 209-212 change the power status in accordance with control signals 202-205.

FIG. 2b is a view showing a structure of a mapping table stored in a pulse position setting part of a PPM modulator of the pulse-modulated wireless communication device of the present first embodiment.

In FIG. 2b, mapping table 250 includes input data which has four values; pulse position data indicating the position to generate a pulse; and pulse position setting output data indicating the type of the control signal to be outputted.

When transmission data 112 is inputted to pulse position setting part 201, PPM modulator 104 determines the pulse position by referring to pre-stored mapping table 250, and outputs control signal 202, 203, 204, or 205 as the pulse position setting output.

For example, when receiving “01” as transmission data 112, pulse position setting part 201 generates a pulse having a position at “the frame start position+T”, and outputs “control signal 203” as the pulse position setting output. As a result, control switch 210 is exclusively energized so as to output clock signal 102 delayed by “T” from “the frame start position+T”, that is, pulse generation timing signal 105 which generates a pulse at “the frame start position+2T”.

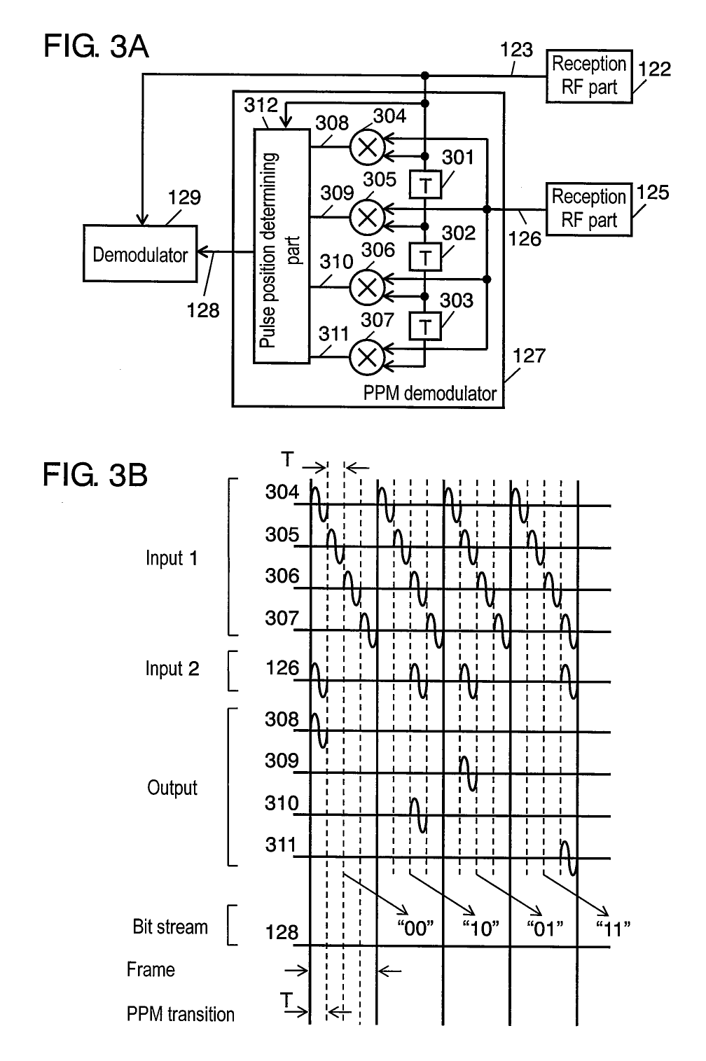

FIG. 3a is a block diagram showing a structure of a PPM demodulator of the pulse-modulated wireless communication device of the present first embodiment.

In FIG. 3a, PPM demodulator 127 includes delay elements 301, 302 and 303; mixers 304, 305, 306 and 307; and pulse position determining part 312. Delay elements 301-303 delay the respective input signals by time “T”. Mixers 304-307 multiply two input signals as correlators. Pulse position determining part 312 latches data mapped by input signals 308, 309, 310 and 311 in the period of clock pulse signal 123 and then outputs the data in the period of clock pulse signal 123.

FIG. 3b is a view showing waveforms of signals in the vicinity of the PPM demodulator of the pulse-modulated wireless communication device of the present first embodiment.

In the waveforms, the frames formed by the interval of clock pulse signal 123 are divided from each other by vertical solid lines, and the transition times “T” in four-valued pulse position modulation are divided from each other by the vertical broken lines in each frame.

FIG. 3b shows the waveforms of signals supplied to mixers 304-307 by delaying clock pulse signal 123 by time “T” using delay elements 301-303, respectively, and the waveform of data pulse signal 126. FIG. 3b further shows the waveforms of signals 308-311 which are the output results of the correlation between data pulse signal 126 and the signals supplied to mixers 304-307.

FIG. 3b further shows the waveform of bit stream 128, which is the result of the pulse position determined by pulse position determining part 312.

Take the first frame shown in FIG. 3b as an example. Data pulse signal 126 has an impulse in the frame start position, so that the correlation is detected by mixer 304 only, and correlation detection result 308 is exclusively outputted in this frame. Pulse position determining part 312 latches each correlation detection result for one frame period defined by clock pulse signal 123, determines the bit combination, and outputs the bit sequence of the transmission data in the next frame time as pulse determination result.

Two pulse-modulated wireless communication devices of the present first embodiment perform data transmission and reception as follows.

In transmission device 100a, transmission data generator 103 generates information to be transmitted and supplies it to PPM modulator 104. Transmission data generator 103 generates the information in accordance with clock signal 102 generated by clock generator 101, which determines the frame period of signal transmission. PPM modulator 104 generates pulse generation timing signal 105 and supplies it to pulse generator 106. Signal 105 is pulse position modulated in accordance with the pulse generation position in the frame period defined by clock signal 102.

Pulse generator 106 generates pulse signal 114, which is an impulse having properties defined for data transmission in accordance with pulse generation timing signal 105. Transmission RF part 107 generates data RF signal “B” by performing an RF process such as amplification or band limiting, and transmits it from antenna 108. Similarly, pulse generator 109 generates pulse signal 113, which is an impulse having properties defined for clock transmission in accordance with clock signal 102. Transmission RF part 110 generates clock RF signal “A” by performing an RF process such as amplification or band limiting, and transmits it from antenna 111.

In reception device 100b, on the other hand, clock RF signal “A” and data RF signal “B”, which are transmitted through different channels from each other are received separately. Reception RF part 122 performs an RF process such as the elimination of undesired signals outside the use band from clock RF signal “A” received by antenna 121, and converts it to clock pulse signal 123. On the other hand, reception RF part 125 performs an RF process such as the elimination of undesired signals outside the use band from data RF signal “B” received by antenna 124, and converts it to data pulse signal 126. PPM demodulator 127 detects the pulse position of data pulse signal 126 relative to clock pulse signal 123 within a frame so as to generate bit stream 128, and demodulator 129 demodulates bit stream 128 into the reception data. Demodulator 129 demodulates bit stream 128 so as to reproduce the transmission data.

This structure of the present first embodiment allows the reception device to appropriately receive reference synchronization information used in PPM modulation so as to maintain the state of synchronization in pulse position, thereby demodulating data signals soon after they are received. The structure also allows the same receiving operation to be performed without a clock regeneration block, that is, an adjustable time base which is required in the conventional pulse-modulated wireless communication devices. As a result, the synchronization circuit which receives pulse position modulated data signals can have a simple structure.

Data communication in the present first embodiment is performed between two pulse-modulated wireless communication devices, one having a transmission device and the other having a reception device. Alternatively, two pulse-modulated wireless communication devices each having both a transmission device and a reception device can perform data communication to obtain the same effect.

Pulse position setting part 201 of the PPM modulator of the transmission device shown in the present first embodiment can be easily formed of a combination of logic elements or can be formed of different logic elements.

Pulse position determining part 312 of the PPM demodulator of the reception device of the present first embodiment can be easily formed of a combination of logic elements or different logic elements.

The bit combination in pulse position determining part 312 of the present first embodiment can be easily determined such as by referring to a pre-stored table data which, for example, has pulse position data and output data in pairs. The pulse position data indicates a pulse position, and the output data indicates the output bit stream corresponding to the pulse position data.

Clock RF signal “A” and data RF signal “B” are transmitted separately and asynchronously by using different channels in the present first embodiment. Therefore, transmission RF part 107 and transmission RF part 110 are separated by using different transmission RF frequencies. However, the same effect can be obtained by using a measure other than frequency separation as long as the channels can be separated. The channel separation can be achieved, for example, by CDMA (Code Division Multiple Access).

The transmission data generator in the transmission device of the present first embodiment generates a transmission signal that has four states as a four-valued digital signal in synchronization with a clock signal. However, the same effect can be obtained by generating a transmission signal that has two states as a two-valued digital signal.

In the present first embodiment, the antennas of the transmission device are positioned close enough to each other and the antennas of the reception device are positioned close enough to each other with respect to the wavelengths of the RF signals. This allows clock RF signal “A” and data RF signal “B” to be under nearly identical propagation conditions such as transmission delay. However, it is alternatively possible that the reception device includes means for controlling minor synchronization errors between the clock pulse signal and the data pulse signal when the distance between the antennas is large with respect to the wavelengths of the RF signals. However, this does not affect the essential element of the present invention, and hence the description thereof will be omitted.

### Second Exemplary Embodiment

A pulse-modulated wireless communication device of a second embodiment of the present invention will be described as follows.

While the device of the first embodiment transmits a clock signal frame by frame, the device of the present second embodiment transmits a clock signal once in a plurality of frames so as to reduce the repetition period of clock signal transmission.

The pulse-modulated wireless communication device of the present second embodiment has the following structure.

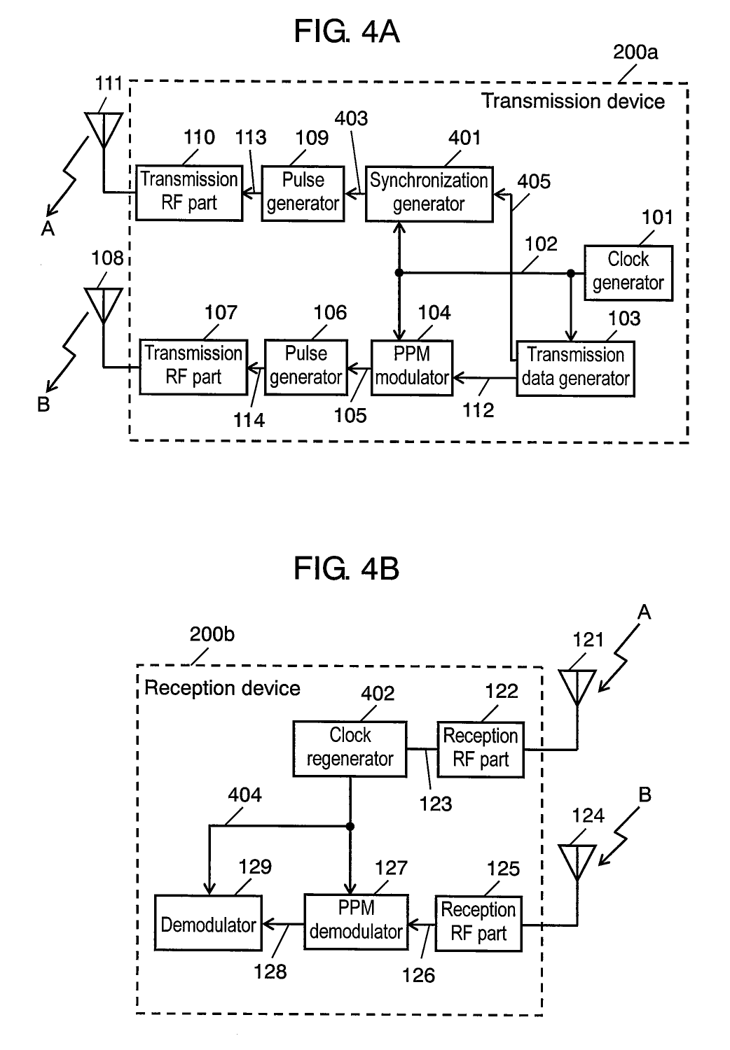

FIG. 4a is a block diagram showing a structure of a transmission device of the pulse-modulated wireless communication device of the present second embodiment. FIG. 4b is a block diagram showing a structure of a reception device of the pulse-modulated wireless communication device of the present second embodiment.

Transmission device 200a and reception device 200b have nearly the same structures as those of the first embodiment, and hence the following description will be focused on their differences.

Transmission device 200a is provided with synchronization generator 401 prior to pulse generator 109. Synchronization generator 401 outputs a pulse at a constant cycle of the clock signal predetermined in accordance with the input of clock signal 102. Synchronization generator 401 is composed of a counter circuit having a shift register.

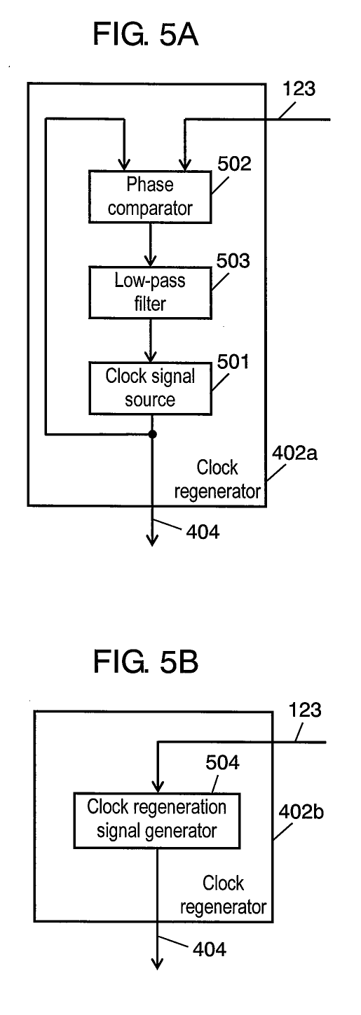

On the other hand, reception device 200b is provided with clock regenerator 402 as a clock signal source of PPM demodulator 127. Clock regenerator 402 includes the clock signal source producing a signal nearly equal to the interval of clock signal 102 of transmission device 200a. Upon receiving clock pulse signal 123, clock regenerator 402 outputs regeneration clock signal 404 synchronous with the frequency and phase of clock pulse signal 123. Clock regenerator 402 can be realized by PLL (Phase Locked Loop) or the like with the structure shown in FIG. 5a or 5b.

FIG. 5a is a block diagram showing a structure of a clock generator of the pulse-modulated wireless communication device of the present second embodiment.

Clock regenerator 402a includes clock signal source 501, phase comparator 502, and low-pass filter 503. Clock signal source 501 outputs a frequency signal close to clock signal 102, and low-pass filter 503 detects as a voltage the degree of phase difference in phase comparator 502. Clock signal source 501 can control the frequency of a VCO (Voltage Controlled Oscillator) or other devices.

This structure allows clock regenerator 402a to detect a phase error between clock pulse signal 123 and the output signal of clock signal source 501 at phase comparator 502 upon receiving clock pulse signal 123, and to supply a control signal as a voltage value from low-pass filter 503 to clock signal source 501. The phase error is reduced so as to synchronize the phases by PLL operation, thereby continuously outputting regeneration clock signal 404 synchronous with clock pulse signal 123.

FIG. 5b is a block diagram showing another structure of the clock regenerator of the pulse-modulated wireless communication device of the present second embodiment.

Clock regenerator 402b includes clock regeneration signal generator 504 having a reset signal input. Generator 504 outputs regeneration clock signal 404 having a frequency close to that of clock signal 102. Clock regeneration signal generator 504 regards clock pulse signal 123 as a reset signal input and makes regeneration clock signal 404 have its initial phase upon receiving a reset signal input, thereby continuously outputting regeneration clock signal 404 synchronous with clock pulse signal 123.

The pulse-modulated wireless communication device of the present second embodiment thus structured operates as follows.

In transmission device 200a, synchronization generator 401 generates synchronizing pulse signal 403 with a constant clock period and transmits clock RF signal “A” and data RF signal “B” in the same manner as in the first embodiment.

On the other hand, reception device 200b receives clock RF signal “A” and data RF signal “B”; generates regeneration clock signal 404 from clock pulse signal 123 received; and demodulates the data based on this regeneration clock signal 404.

In the present second embodiment thus structured, the transmission device can transmit a data signal modulated by multi-valued pulse position modulation as a pulse train at a constant cycle of the clock signal. On the other hand, the reception device can generate a reproduction clock pulse by the simple-structured synchronization circuit to obtain the same demodulation result as in the case of transmitting a clock signal frame by frame. In addition, the frequency of transmission of a clock signal is minimized in order to maintain the synchronization accuracy, thereby reducing transmit power and thus reducing power consumption.

Synchronization generator 401 outputs a synchronizing pulse signal at the constant cycle of a clock signal in the present second embodiment, but alternatively can output the signal in information units to obtain the same effect. For example, synchronization generator 401 can be designed to output the synchronizing pulse signal in a fixed amount of bytes to be outputted by the transmission data generator. More specifically, in FIGS. 4a and 4b, transmission data generator 103 provides synchronization generator 401 with synchronization request signal 405 at the boundaries of information units. Only when receiving synchronization request signal 405 from transmission data generator 103, synchronization generator 401 outputs and transmits synchronizing pulse signal 403 by pulsing clock signal 102. On the other hand, the reception device determines the boundaries between the information units from clock pulse signal 123, refers to the information as additional information, and demodulates it.

Synchronization generator 401 outputs a synchronizing pulse signal at the constant cycle of a clock signal in the present second embodiment. Alternatively, clock RF signal “A” can have a variable pulse interval to obtain the same effect. The synchronizing pulse signal is variably controlled so as to be continuously outputted when it is pulled into synchronism immediately after communication is started and so as to be outputted less frequently after the establishment of synchronization. In this manner, a large number of synchronizing pulse signals can be used when being pulled into synchronism because they are important in this period. In contrast, fewer unnecessary synchronizing pulse signals can be transmitted after synchronization is established because synchronizing pulse signals are not very important in this period. Thus, payload in communication can be maximized.

### Third Exemplary Embodiment

A pulse-modulated wireless communication device of a third embodiment of the present invention will be described as follows.

While the device of the second embodiment transmits a clock signal once in a plurality of frames, the device of the present third embodiment provides a clock signal on the transmission device side with additional information such as parity bits, thereby allowing the reception device to perform error detection or error correction.

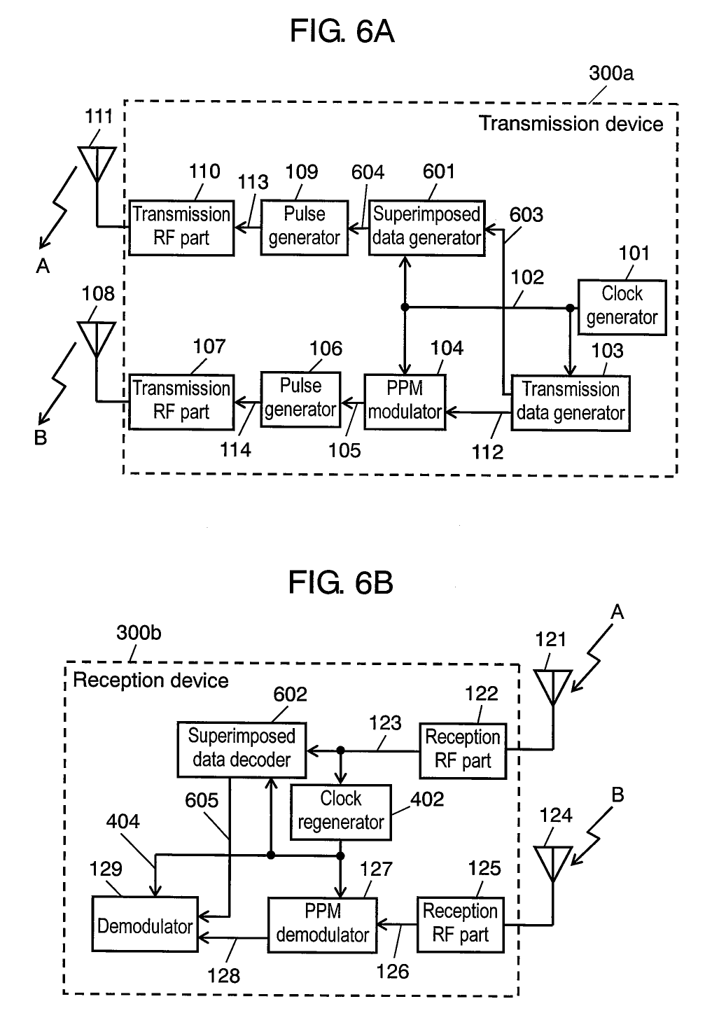

The pulse-modulated wireless communication device of the present third embodiment has the following structure. FIG. 6a is a block diagram showing a structure of a transmission device of the pulse-modulated wireless communication device of the present third embodiment. FIG. 6b is a block diagram showing a structure of a reception device of the pulse-modulated wireless communication device of the present third embodiment.

Transmission device 300a and reception device 300b have nearly the same structures as those of the first embodiment, and hence the following description will be focused on their differences.

Transmission device 300a is provided with superimposed data generator 601 in place of synchronization generator 401 of the second embodiment. Superimposed data generator 601 superimposes information onto clock signal 102 and then outputs superimposed pulse signal 604. On the other hand, reception device 300b is provided with superimposed data decoder 602. Superimposed data decoder 602 receives clock signal 404 and clock pulse signal 123; extracts superimposed data 605 indicating the information superimposed onto clock pulse signal 123; and supplies superimposed data 605 to demodulator 129.

Since clock signal 102 is transmitted once in a plurality of frames, it becomes possible to insert information bits, which is impossible in the structure of the first embodiment where the clock signal is transmitted continuously. In other words, clock signal 102 consisting of a plurality of bits can include parity bits as information bits in the information unit defined by a plurality of frames such as a 1-bit unit or a 1-packet unit, or information for error correction.

The pulse-modulated wireless communication device of the present third embodiment thus structured operates as follows.

In transmission device 300a, transmission data generator 103 provides superimposed data generator 601 with additional information data 603 at the boundaries of the information units in addition to synchronization request signal 405 of the second embodiment. Superimposed data generator 601 generates superimposed pulse signal 604 including the additional information in the data region defined by a plurality of clocks after the clock signal, thereby allowing transmission device 300a to transmit clock RF signal “A”. Transmission data generator 103 provides a data region corresponding to a plurality of clocks after the clock signal 102; pulses a signal added with additional information such as parity bits by ASK (Amplitude Shift Keying); and inserts the signal into the data region.

In reception device 300b, on the other hand, clock regenerator 402 synchronizes regeneration clock signal 404 with the initial pulse of clock pulse signal 123 in the same manner as in the second embodiment. Clock pulse signal 123 is also provided to superimposed data decoder 602. Superimposed data decoder 602 decodes superimposed data 605, which is the additional information contained in the second and subsequent pulses of clock pulse signal 123, and outputs it to demodulator 129.

In the present third embodiment thus structured, a synchronization pulse train is transmitted at a specified symbol rate, and additional information such as parity bits for a data signal is superimposed onto the synchronization signal. This makes it possible to perform error detection and error correction using additional information such as parity bits, without compressing the payload of information bits. As a result, the pulse-modulated wireless communication device is improved in reliability.

The data region, which is structured using ASK in which data is transmitted depending on the presence or absence of a pulse in the present third embodiment, can alternatively be based on pulse position modulation or bi-phase modulation, which is two-valued phase modulation.

### Fourth Exemplary Embodiment

A pulse-modulated wireless communication device of a fourth embodiment of the present invention will be described as follows.

While a clock signal is transmitted frame by frame without being modulated in the first embodiment, a clock signal is transmitted after being pulse position modulated in the present fourth embodiment. This can reduce frequency irregularities in the frequency spectrum of the clock RF signal, which is so-called “whitening” and results from the repetition period of the clock signal. This improves the transmit power efficiency of the clock signal, thereby improving the reception device sensitivity of the clock RF signal and reducing power consumption.

The pulse-modulated wireless communication device of the present fourth embodiment has the following structure.

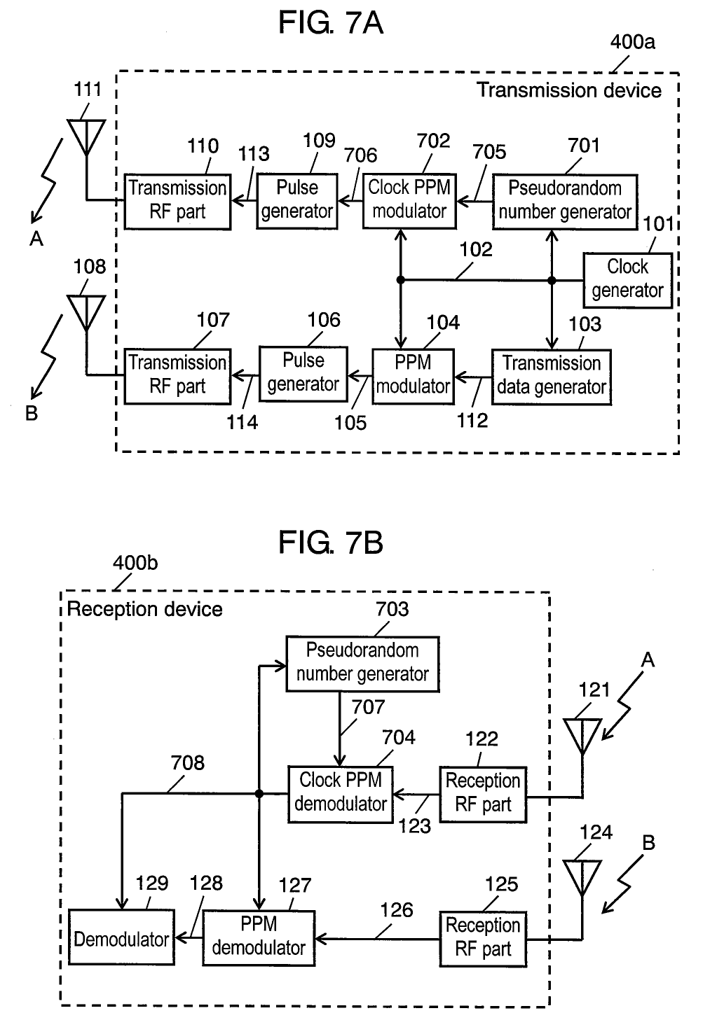

FIG. 7a is a block diagram showing a structure of a transmission device of the pulse-modulated wireless communication device of the fourth embodiment of the present invention. FIG. 7b is a block diagram showing a structure of a reception device of the pulse-modulated wireless communication device of the fourth embodiment of the present invention. Transmission device 400a and reception device 400b have nearly the same structures as those of the first embodiment, and hence the following description will be focused on their differences.

Transmission device 400a is provided with pseudorandom number generator 701 and clock PPM modulator 702. Pseudorandom number generator 701 generates pseudorandom number sequence data 705 in synchronization with clock signal 102. Clock PPM modulator 702 pulse position modulates clock signal 102 in accordance with pseudorandom number sequence data 705 and outputs random number pulse signal 706.

Reception device 400b, on the other hand, is provided with pseudorandom number generator 703 and clock PPM demodulator 704. Pseudorandom number generator 703 generates pseudorandom number sequence data 707 which is the same series as in transmission device 400a. Clock PPM demodulator 704 performs PPM demodulation by using pseudorandom number sequence data 707 outputted from pseudorandom number generator 703 and generates random number regeneration clock signal 708.

The pulse-modulated wireless communication device of the present fourth embodiment thus structured operates as follows.

In transmission device 400a, pseudorandom number generator 701 generates pseudorandom number sequence data 705 by receiving clock signal 102 and provides data 705 as a modulation code to clock PPM modulator 702. Clock PPM modulator 702 pulse position modulates pseudorandom number sequence data 705 so as to generate random number pulse signal 706 and provides signal 706 to pulse generator 109.

In reception device 400b, on the other hand, pseudorandom number generator 703 provides clock PPM demodulator 704 with pseudorandom number sequence data 707 which is equal to pseudorandom number sequence data 705 generated by pseudorandom number generator 701 of transmission device 400a. Clock PPM demodulator 704 PPM demodulates clock pulse signal 123 so as to generate random number regeneration clock signal 708. The phase of pseudorandom number sequence data 707 from pseudorandom number generator 703 is synchronized with the phase on the modulation side by using sweep means or the like when synchronization is established.

In the present fourth embodiment thus structured, the synchronization signal modulated by a random pattern using pseudorandom number sequence data is transmitted to a synchronization channel and regenerated by the same random pattern on the transmission device side so as to smooth the frequency spectrum of the clock RF signal. As a result, after the synchronization channel is pulled into synchronism, no high precision synchronization circuit is necessary, thereby improving the communication efficiency of the synchronization channel signal.

Clock signal 102 generally has the property of having a concentration of power at the multiples of the repetition frequency of a clock or at fractional frequency components. The present fourth embodiment, however, performs pulse position modulation to generate clock RF signal “A” having frequency characteristics uniformly within the band due to the frequency dispersion obtained by the pseudorandom number sequence data. As a result, the power within the frequency band can be used densely to obtain an efficient transmission signal.

### Fifth Exemplary Embodiment

A pulse-modulated wireless communication device of a fifth embodiment of the present invention will be described as follows.

While the fourth embodiment uses pulse position modulation, the present fifth embodiment uses bi-phase modulation instead of pulse position modulation. This structure of the present fifth embodiment can provide the same advantage as in the fourth embodiment.

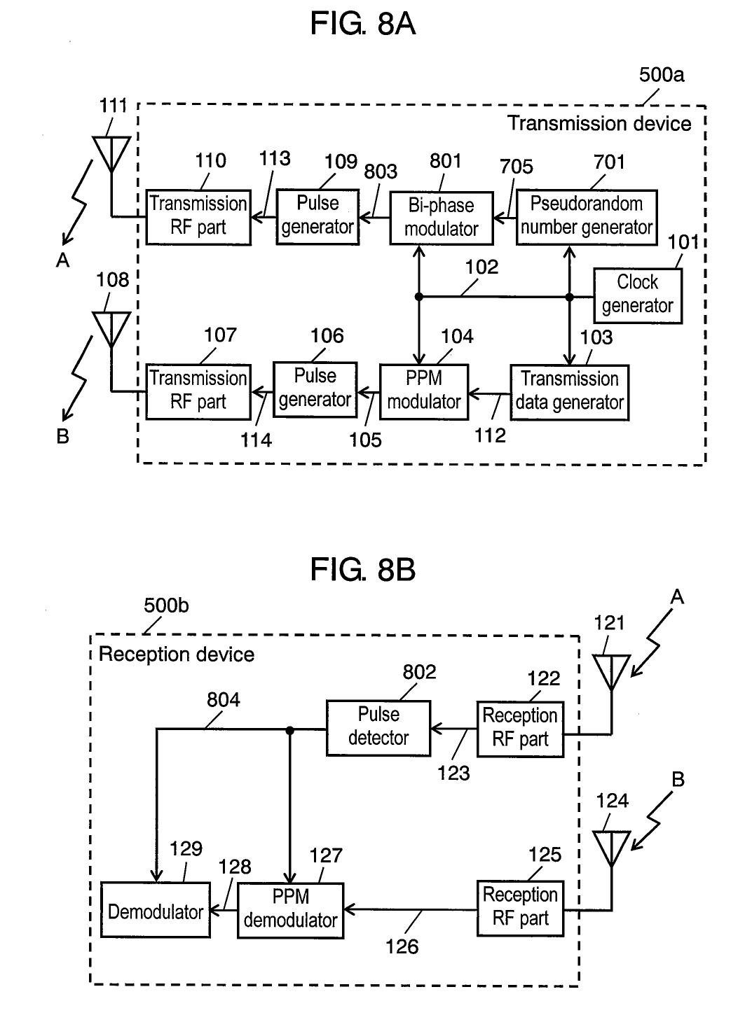

FIGS. 8a and 8b are block diagrams showing structures of a transmission device and a reception device of the pulse-modulated wireless communication device of the fifth embodiment of the present invention. The device of the fifth embodiment differs from the device of the fourth embodiment in that the modulator is based on bi-phase modulation.

The structure of the present fifth embodiment with bi-phase modulation and the structure of the fourth embodiment with pulse position modulation are different as follows.

Transmission device 500a is provided with bi-phase modulator 801 which bi-phase modulates clock signal 102 in accordance with pseudorandom number sequence data 705 and outputs random number pulse signal 803. Reception device 500b, on the other hand, is provided with pulse detector 802 instead of pseudorandom number generator 703 and clock PPM demodulator 704. Pulse detector 802 detects the repetition frequency of bi-phase modulation by envelope detection of an input pulse so as to detect the synchronization timing and generates bi-phase regeneration clock signal 804.

In reception device 500b with bi-phase modulation, when bi-phase regeneration clock signal 804 is regenerated from clock pulse signal 123, it is possible to detect the basic pulse interval of bi-phase modulation by envelope detection or other methods without performing reverse spreading by pseudorandom number generator 703 and bi-phase demodulation. Therefore, the structure of the present fifth embodiment is effective to achieve a simple receiving structure.

### Sixth Exemplary Embodiment

A pulse-modulated wireless communication device of a sixth embodiment of the present invention will be described as follows.

In the device of the present sixth embodiment, when signal transmission is performed separately and concurrently to a plurality of terminals, a data RF signal is transmitted separately, and a clock RF signal is shared among the terminals. This reduces the size of the circuit structure of the transmission device and hence power consumption.

The pulse-modulated wireless communication device of the present sixth embodiment has the following structure.

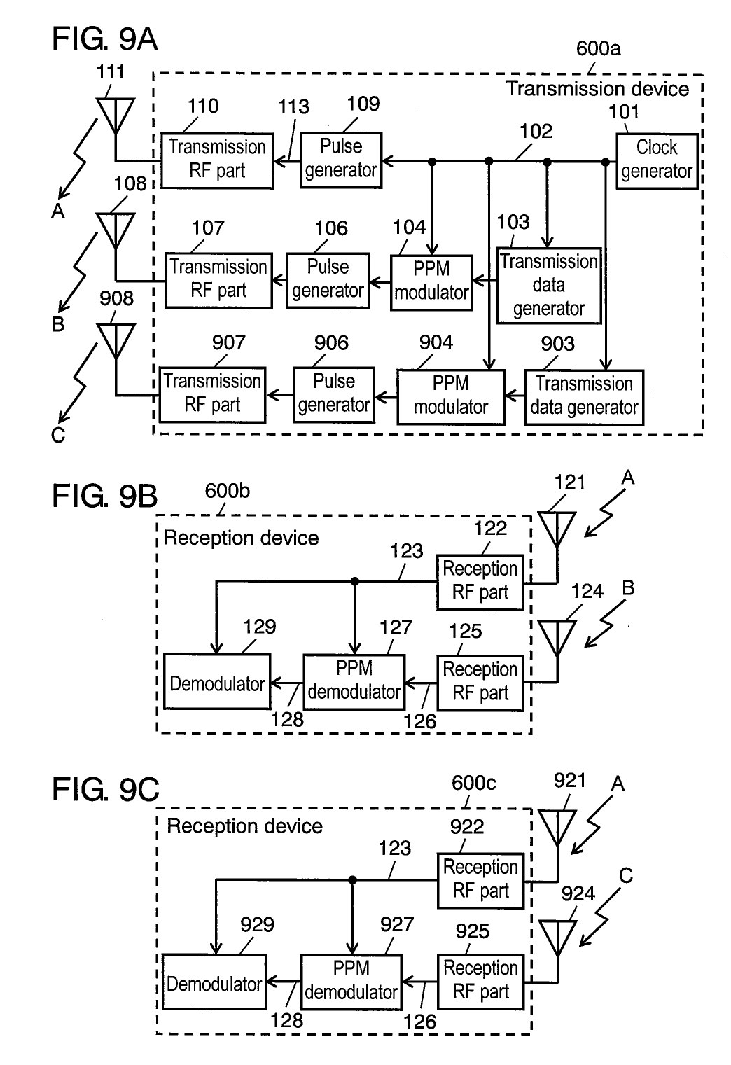

FIG. 9a is a block diagram showing a structure of a transmission device of the pulse-modulated wireless communication device of the present sixth embodiment. FIG. 9b is a block diagram showing a structure of a reception device of a first pulse-modulated wireless communication device of the present sixth embodiment. FIG. 9c is a block diagram showing a structure of a reception device of a second pulse-modulated wireless communication device of the present sixth embodiment.

Transmission device 600a and reception devices 600b, 600c have nearly the same structures as those of the first embodiment, and hence the following description will be focused on their differences.

Transmission device 600a is provided, in addition to the components shown in the first embodiment, with transmission data generator 903, PPM modulator 904, pulse generator 906, transmission RF part 907, and antenna 908. Thus, transmission device 600a consists of two data transmission devices. Reception device 600b and reception device 600c are identical in structure. Reception device 600c includes antenna 921, reception RF part 922, antenna 924, reception RF part 925, PPM demodulator 927, and demodulator 929, and shares the receiving system of clock RF signal “A” with reception device 600b.

The pulse-modulated wireless communication device of the present sixth embodiment thus structured operates as follows.

Data modulation operation in transmission device 600a and data demodulation operation in reception devices 600b, 600c are nearly the same as in the first embodiment. Transmission device 600a generates clock RF signal “A” and data RF signals “B” and “C”, and transmits clock RF signal “A” and data RF signal “B” to reception device 600b, and clock RF signal “A” and data RF signal “C” to reception device 600c. Reception device 600b receives clock RF signal “A” and data RF signal “B” and demodulates the data. Reception device 600c receives clock RF signal “A” and data RF signal “C” and demodulates the data.

In the present sixth embodiment thus structured, when a plurality of pulse-modulated wireless communication devices perform data communication concurrently, one device can transmit different data to the other devices concurrently by sharing a synchronization channel so as to improve the use efficiency of a synchronization channel signal.

Although the present sixth embodiment has two data transmission devices and two data reception devices, three or more data transmission devices and three or more reception devices can share a single clock RF signal to obtain the same effect.

### Seventh Exemplary Embodiment

A pulse-modulated wireless communication device of a seventh embodiment of the present invention will be described as follows.

In the device of the present seventh embodiment, a signal having continuous phase characteristics between pulse signals is transmitted as a clock RF signal and used as an LO signal (reference signal) for frequency conversion at the time of demodulation, instead of providing the reception device with an oscillator which generates the LO signal. This reduces the size of the circuit structure of the reception device, thereby reducing power consumption.

The pulse-modulated wireless communication device of the present seventh embodiment has the following structure.

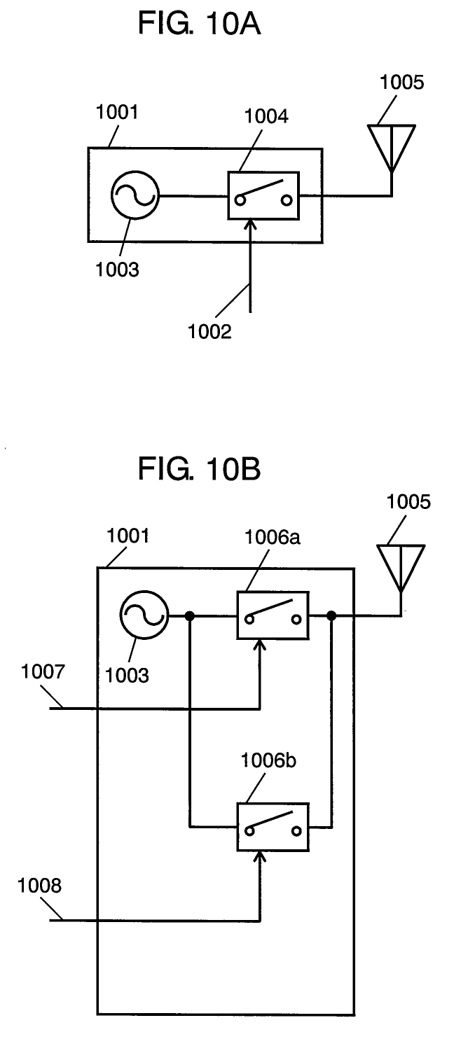

FIG. 10a is a block diagram showing a structure of a transmission RF part in a transmission device of the pulse-modulated wireless communication device of the present seventh embodiment. The other structures are identical to those in the first embodiment, and hence the description thereof will be omitted.

In FIG. 10a, transmission RF part 1001 in the transmission device consists of RF signal source 1003 and pulse shortening circuit 1004. Pulse shortening circuit 1004 passes or blocks a signal outputted from RF signal source 1003 based on pulse signal 1002 generated by the pulse generator; converts the signal into a short pulse signal; and outputs it as a clock RF signal or a data RF signal. Transmission RF part 1001 also includes antenna 1005 for transmission.

Pulse shortening circuit 1004 can be composed of a switch circuit or a mixer circuit. The RF signal source is preferably composed of a continuous oscillation circuit because it is required to have continuous phase characteristics between pulses. However, it is alternatively possible to use a circuit that oscillates intermittently; a method for generating a signal by extracting the desired band of an impulse signal; or a method for digitally superimposing signals as long as the RF signal source has a phase adjustment function. The continuous oscillation circuit facilitates the realization of continuous phase characteristics, while the other methods can reduce the operating time to achieve low power consumption.

FIG. 10b is a block diagram showing another structure of the transmission RF part in the transmission device of the pulse-modulated wireless communication device of the present seventh embodiment. The other structures are identical to those in the first embodiment, and hence the description thereof will be omitted.

In FIG. 10b, the same signal from RF signal source 1003 is subjected to a pulse shortening process using pulse shortening circuits 1006a and 1006b based on clock signal-based pulse signal 1007 and transmission data-based pulse signal 1008, respectively, and then transmitted from antenna 1005. This can simplify the structure of transmission RF part 1001, thereby reducing the number of antennas 1005.

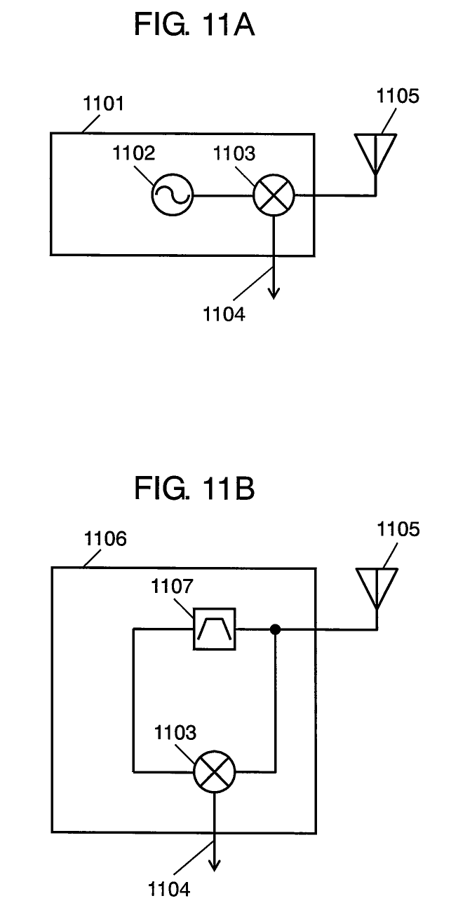

FIG. 11a is a block diagram showing a structure of a reception RF part in a reception device of the pulse-modulated wireless communication device of the present seventh embodiment. The other structures are identical to those in the first embodiment, and hence the description thereof will be omitted.

In FIG. 11a, reception RF part 1101 consists of RF signal source 1102 and down mixer 1103. The clock RF signal and the data RF signal transmitted from the transmission device are high-frequency signals and must be converted to low-frequency signals to make a receiving process possible. The RF signal received by antenna 1105 is inputted to down mixer 1103, then down-converted to a signal having an appropriate frequency by using the signal from RF signal source 1102 as the LO signal, and outputted as pulse signal 1104.

FIG. 11b is a block diagram showing another structure of the reception RF part in the reception device of the pulse-modulated wireless communication device of the present seventh embodiment. The other structures are identical to those in the first embodiment, and hence the description thereof will be omitted.

In reception RF part 1106 shown in FIG. 11b, a signal received by antenna 1105 is separated into two signals: one is inputted to down mixer 1103 in the same manner as in FIG. 11a, and the other is inputted to band-limiting filter 1107. The signal to be inputted as an LO signal to down mixer 1103 is converted to a continuous signal by exclusively extracting the frequency of the LO signal from a narrow band.

This structure makes it unnecessary to provide the LO signal source for reception, thereby simplifying the reception device structure and requiring low power consumption as compared with the structure shown in FIG. 11a.

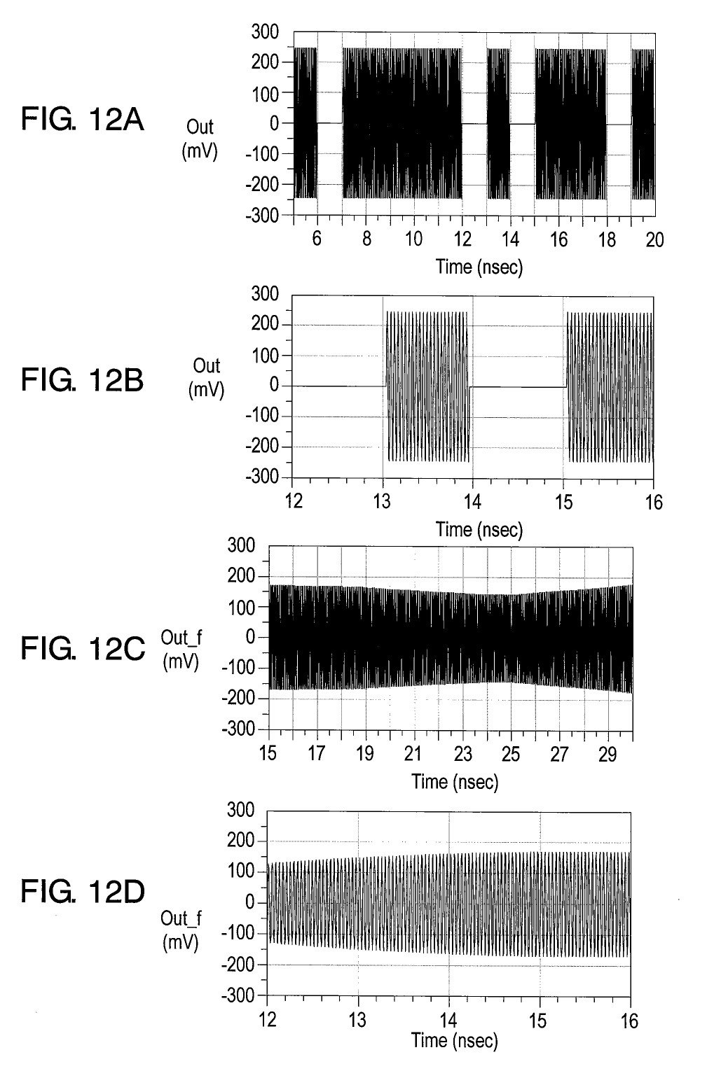

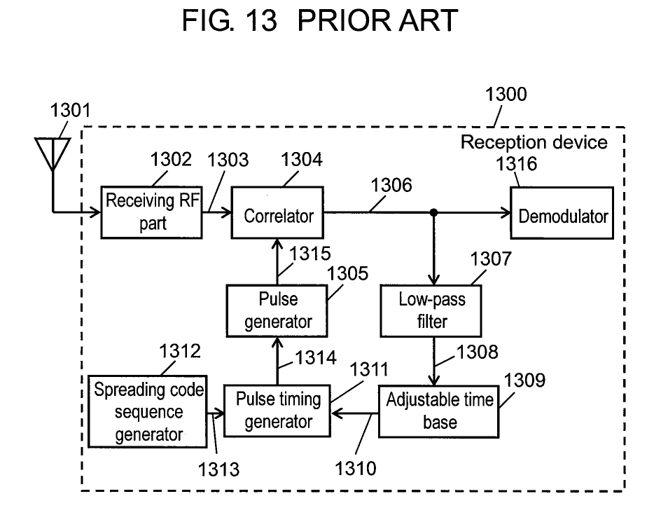

FIGS. 12a to 12d show waveforms of signals received by the reception RF part shown in FIG. 11b.

FIG. 12a shows a signal received by antenna 1105, and FIG. 12b shows an enlarged part of the signal. These drawings indicate that a pulsed signal received by antenna 1105 contains sinusoidal components.

FIG. 12c shows an output signal of band-limiting filter 1107, and FIG. 12d shows an enlarged part of the signal. These drawings indicate that the output signal of band-limiting filter 1107 is a continuous signal converted from the intermittent signal.

The signals shown in FIGS. 12a to 12d have an RF frequency band of 25 GHz, a pulse width of 1 ns, and a band-limiting filter bandwidth of 300 MHz. In general, the RF signal source frequency of the transmission device and the RF signal source frequency of the reception device are generated using different reference signal sources, making it necessary to correct frequency deviation all the time. In contrast, the structure of the present embodiment does not need to correct the frequency deviation because a signal extracted from the RF signal is used as the LO signal, thereby simplifying the circuit structure.

In the present seventh embodiment thus structured, a signal having continuous phase characteristics between pulse signals is transmitted as the clock RF signal and used as the LO signal for frequency conversion at the time of demodulation. This can reduce the size of the circuit structure of the reception device and reduce power consumption.

In the pulse-modulated wireless communication device of each of the aforementioned embodiments, either PPM modulator 104 or PPM demodulator 127 is structured based on pulse position modulation in which the pulse position is modulated in accordance with transmission data. However, the present invention can be alternatively based on pulse amplitude modulation in which pulse amplitude is modulated according to transmission data; pulse phase modulation in which pulse phase is modulated according to transmission data; or pulse frequency modulation in which pulse frequency is modulated according to transmission data. Whichever of the modulation schemes is used, the reception device takes synchronization at the time of data reception in the same manner as in each of the embodiments with PPM modulation. Therefore, it goes without saying that regardless of the modulation scheme used, the reception device can maintain a synchronized state at the time of data reception, and the signal can be demodulated soon after data reception.

### INDUSTRIAL APPLICABILITY

The pulse-modulated wireless communication device of the present invention is useful as small and inexpensive PPM modulation wireless device with high productivity.

1. A pulse-modulated wireless communication device comprising:
a clock generator for generating a clock signal indicating each frame timing of a transmission signal;
a first pulse generator for generating a pulse signal at a timing of the clock signal;
a first transmission converter for signal-converting the pulse signal generated by the first pulse generator so as to generate a clock conversion signal and for outputting the clock conversion signal to a synchronization signal channel;
a transmission data generator for generating transmission data in synchronization with the timing of the clock signal;
a pulse modulator for pulse-modulating the transmission data and outputting a pulse generation timing signal;
a second pulse generator for generating a pulse signal at a timing of the pulse generation timing signal; and
a second transmission converter for signal-converting the pulse signal generated by the second pulse generator so as to generate a data conversion signal and for outputting the data conversion signal to a data signal channel different from the synchronization signal channel.

2. A pulse-modulated wireless communication device comprising:
a first reception converter for receiving a-clock conversion signal from a synchronization signal channel, the clock conversion signal being obtained by signal-converting a clock pulse signal, and for generating the clock pulse signal;
a second reception converter for receiving a data conversion signal from a data signal channel different from the synchronization signal channel, the data conversion signal being obtained by signal-converting a data pulse signal, and for generating the data pulse signal;
a pulse demodulator for pulse-demodulating the data pulse signal on a basis of the clock pulse signal and for outputting a bit stream; and
a demodulator for demodulating the bit stream into reception data on the basis of the clock pulse signal.

3. The pulse-modulated wireless communication device of claim 1, wherein the pulse modulator comprises:
a pulse position setting part for setting modulated pulse positions indicating pulse positions of pulse modulation in accordance with the transmission data and for outputting pulse control signals corresponding to the modulated pulse positions;
a plurality of multi-stage delay parts for outputting the clock signals delayed respectively according to all the pulse positions of pulse modulation; and
a plurality of switches for selecting and outputting output signals of the plurality of multi-stage delay parts in accordance with the pulse control signals.

4. The pulse-modulated wireless communication device of claim 2, wherein the pulse demodulator comprises:
a plurality of multi-stage delay parts for outputting the clock pulse signals delayed respectively according to all the pulse positions of pulse modulation;
a plurality of correlators for detecting correlation between output signals of the plurality of multi-stage delay parts and the data pulse signal and for outputting correlation signals; and
a pulse position determining part for determining the pulse positions of pulse modulation in accordance with the correlation signals and for outputting a bit stream.

5. The pulse-modulated wireless communication device of claim 1 further comprising:
a synchronization generator for generating a synchronizing pulse signal, the synchronizing pulse signal being a pulse signal having a constant cycle in accordance with the clock signal, wherein
the first pulse generator generates a pulse signal at a timing of the synchronizing pulse signal.

6. The pulse-modulated wireless communication device of claim 2 further comprising:
a clock regenerator for generating a regeneration clock signal from a clock pulse signal, the regeneration clock signal indicating each frame timing, and the clock pulse signal having a constant cycle, wherein
the pulse demodulator pulse-demodulates the data pulse signal on a basis of the regeneration clock signal and outputs a bit stream; and
the demodulator demodulates the bit stream into reception data on the basis of the regeneration clock signal.

7. The pulse-modulated wireless communication device of claim 6, wherein
the clock regenerator comprises:
a clock signal source operating at a frequency close to a preset frame timing and capable of being frequency-controlled by an external voltage;
a phase comparator for outputting an amount of error indicating a phase difference between the clock signal source and the clock pulse signal; and
a low-pass filter for converting the amount of error to a control voltage and for outputting the control voltage, and
the clock regenerator controls a frequency of the clock signal source by the control voltage.

8. The pulse-modulated wireless communication device of claim 6, wherein the clock regenerator comprises:
a clock regeneration signal generator operating at a frequency close to a preset frame timing and capable of being reset in such a manner that an output signal of the clock regeneration signal generator restores an initial phase by an external signal, the clock regeneration signal generator synchronizing a phase of the regeneration clock signal with the clock pulse signal, upon receiving the clock pulse signal.

9. The pulse-modulated wireless communication device of claim 1 further comprising:
a superimposed data generator for generating a superimposed pulse signal, the superimposed pulse signal consisting of a pulse signal having a constant cycle in accordance with the clock signal, and a pulse signal obtained by superimposing additional information data indicating additional information of the transmission data onto the clock signal, wherein
the transmission data generator generates the additional information data together with the transmission data in synchronization with the timing of the clock signal, and
the first pulse generator generates a pulse signal at a timing of the superimposed pulse signal.

10. The pulse-modulated wireless communication device of claim 2 further comprising:
a clock regenerator for generating a regeneration clock signal from a clock pulse signal, the regeneration clock signal indicating each frame timing, and the clock pulse signal being obtained by superimposing a pulse signal having a constant cycle with additional information data indicating additional information of the transmission data; and
a superimposed data decoder for generating superimposed data by extracting the additional information data from the clock pulse signal in accordance with the regeneration clock signal, wherein
the demodulator demodulates the superimposed data and the bit stream into reception data on a basis of the reproduction clock signal.

11. The pulse-modulated wireless communication device of claim 1 further comprising:
a pseudorandom number generator for generating pseudorandom number sequence data in accordance with the clock signal; and
a clock pulse modulator for generating a random number pulse signal by pulse-modulating the clock signal in accordance with the pseudorandom number sequence data, wherein
the first pulse generator generates a pulse signal at a timing of the random number pulse signal.

12. The pulse-modulated wireless communication device of claim 2 further comprising:
a clock pulse demodulator for generating a random number regeneration clock signal from a clock pulse signal, the random number regeneration clock signal indicating each frame timing, and the clock pulse signal being pulse-modulated in accordance with pseudorandom number sequence data; and
a pseudorandom number generator for generating the pseudorandom number sequence data at a timing of the random number regeneration clock signal, wherein
the pulse demodulator pulse-demodulates the data pulse signal on a basis of the random number regeneration clock signal, and outputs a bit stream, and
the demodulator demodulates the bit stream into reception data on the basis of the random number regeneration clock signal.

13. The pulse-modulated wireless communication device of claim 1 further comprising:
a pseudorandom number generator for generating pseudorandom number sequence data in accordance with the clock signal; and
a bi-phase modulator for generating a random number pulse signal by bi-phase modulating the clock signal in accordance with the pseudorandom number sequence data, wherein
the first pulse generator generates a pulse signal at a timing of the random number pulse signal.

14. The pulse-modulated wireless communication device of claim 2 further comprising:
a pulse detector for detecting a repetition frequency of bi-phase modulation from a clock pulse signal which is bi-phase modulated in accordance with pseudorandom number sequence data and for generating a bi-phase regeneration clock signal indicating each frame timing, wherein
the pulse demodulator pulse-demodulates the data pulse signal on a basis of the bi-phase regeneration clock signal and outputs a bit stream; and
the demodulator demodulates the bit stream into reception data on the basis of the bi-phase regeneration clock signal.

15. The pulse-modulated wireless communication device of claim 1 comprising: the plurality of transmission data generators; the plurality of pulse modulators; the plurality of second pulse generators; and the plurality of second transmission converters, wherein
the transmission data to be transmitted to a plurality of destination devices is modulated to be synchronous with the timing of the clock signal so as to generate the data conversion signal, and is then transmitted to the data signal channels set correspondingly to the destination devices.

16. The pulse-modulated wireless communication device of claim 2, wherein
the second reception converter selects and receives a preset one of the data conversion signals from the plurality of data signal channels so as to generate the data pulse signal.

17. The pulse-modulated wireless communication device of claim 1, wherein
the pulse modulator is based on one of pulse amplitude modulation in which pulse amplitude is modulated; pulse phase modulation in which pulse phase is modulated; and pulse frequency modulation in which pulse frequency is modulated.

18. The pulse-modulated wireless communication device of claim 2, wherein
the pulse demodulator is based on one of pulse amplitude modulation in which pulse amplitude is modulated; pulse phase modulation in which pulse phase is modulated; and pulse frequency modulation in which pulse frequency is modulated.

19. The pulse-modulated wireless communication device of any one of claims 1 to 16, wherein
the synchronization signal channel uses a frequency band narrower than the data signal channels.
